(19) United States
(12) Patent Application Publication
(10) Pub. No.: US 2009/0162984 A1
(43) Pub. Date: Jun. 25, 2009

(54) METHOD FOR MANUFACTURING SEMICONDUCTOR DEVICE

(76) Inventor: Chung Kyung Jung, Anyang-si (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/269,111

(22) Filed: Nov. 12, 2008

(30) Foreign Application Priority Data
Dec. 24, 2007 (KR) 10-2007-0135987

(51) Int. Cl. H01L 21/336

(52) U.S. Cl. 438/287; 257/E21.423

(57) ABSTRACT

Disclosed are methods for manufacturing a semiconductor device. One method includes the steps of forming a gate electrode on a semiconductor substrate, sequentially forming a first oxide layer, a nitride layer and a second oxide layer on the semiconductor substrate including the gate electrode, dry-etching the second oxide layer, wet-etching the nitride layer, and forming source and drain regions at sides of the gate electrode by implanting ions into the semiconductor substrate on which the first oxide layer is formed. According to the method, in the process of forming a gate spacer in the semiconductor device, an oxide layer of the gate spacer remains on the source and drain regions, and then an ion implantation process is performed, so that plasma damage and current leakage can be inhibited from occurring in the source and drain regions. Thus, device characteristics of a CMOS image sensor can be improved.

### CROSS-REFERENCE TO RELATED APPLICATION

The present application claims the benefit under 35 U.S.C. § 119 of Korean Patent Application No. 10-2007-0135987, filed Dec. 24, 2007, which is hereby incorporated by reference in its entirety.

### BACKGROUND

In general, an image sensor is a semiconductor device that converts an optical image into electrical signals. The image sensor is typically classified as a Charge Coupled Device (CCD) image sensor, in which individual Metal Oxide Semiconductor (MOS) capacitors are located closely to each other such that charge carriers are stored in or discharged from the capacitors, or a CMOS image sensor employing a switching mode to sequentially detect output by providing MOS transistors corresponding to the number of pixels through a CMOS technology that uses peripheral devices, such as a control circuit and a signal processing circuit.

The CCD image sensor requires high power consumption in order to obtain permissible charge transfer efficiency. Further, since the CCD image sensor requires an additional support circuit for adjusting an image signal or generating standard video output, the CCD image sensor may not be highly integrated. In order to solve such problems, the CMOS image sensor has been recently proposed as an alternative of the CCD image sensor.

The CMOS image sensor has a relatively simple structure as compared with the CCD image sensor. Further, the CMOS image sensor uses a highly developed CMOS manufacturing process, so that the CMOS image sensor can be highly integrated and can reduce power consumption. In general, a pixel of the CMOS image sensor may include a photodiode, which is a photodetector, and one or more FETs (field effect transistors) (hereinafter, referred to as transistors) for transmitting and outputting charges stored in the photodiode.

In the transistor used for driving the conventional CMOS image sensor, when directly implanting high concentration impurities into a semiconductor substrate in order to form source and drain regions for the transistor, surface defects may occur in the semiconductor substrate.

The surface defects may cause generation of EHPs (electron-hole pairs). Thus, although light is not incident from an exterior, dark current may occur and the image sensor may abnormally operate, causing defect of the image sensor.

### BRIEF SUMMARY

Embodiments of the present invention provide methods for manufacturing a semiconductor device.

An embodiment of the present invention provides a method for manufacturing a semiconductor device, which can inhibit plasma damage and current leakage from occurring by forming a remaining oxide layer after performing dry and wet etching processes when forming a gate spacer of the semiconductor device.

A method for manufacturing a semiconductor device according to an embodiment can include forming a gate electrode on a semiconductor substrate, sequentially forming a first oxide layer, a nitride layer and a second oxide layer on the semiconductor substrate on which the gate electrode is formed, dry-etching the second oxide layer, wet-etching the nitride layer, and forming source and drain regions at both sides of the gate electrode by implanting ions into the semiconductor substrate on which the first oxide layer remains.

In another embodiment, a method for manufacturing a semiconductor device can include forming a gate electrode on a semiconductor substrate, sequentially forming an insulating layer on the semiconductor substrate on which the gate electrode is formed, etching the insulating layer such that a part of the insulating layer remains on the semiconductor substrate at both sides of the gate electrode and on sidewalls of the gate electrode, forming source and drain regions at both sides of the gate electrode by implanting ions into the semiconductor substrate through the part of the insulating layer remaining on the semiconductor substrate, and removing the remaining insulating layer.

According to an embodiment, when forming a gate spacer in the semiconductor device, an oxide layer is formed to remain on source and drain regions to inhibit plasma damage and current leakage from occurring during an ion implantation process, thereby improving device characteristics of a CMOS image sensor.

Further, according to an embodiment, current leakage of a driving transistor of an image sensor can be inhibited from occurring, so that characteristics of an image sensor can be improved.

### BRIEF DESCRIPTION OF THE DRAWINGS

FIGS. 1 to 6 are sectional views illustrating a procedure for manufacturing a semiconductor device according to an embodiment.

### DETAILED DESCRIPTION

Hereinafter, a method for manufacturing a semiconductor device according to an embodiment will be described in detail with reference to the accompanying drawings. The size (dimension) of elements shown in the drawings may be magnified for the purpose of clear explanation and the real size of the elements may be different from the size of elements shown in drawings. In addition, the present invention may not include all the elements shown in the drawings and may not be limited thereto. The elements except for essential elements of the present invention can be omitted or added without limitation.

In the description of embodiments, it will be understood that when a layer (or film) is referred to as being ‘on/above/over/upper’ another layer or substrate, it can be directly on another layer or substrate, or intervening layers may also be present. Further, it will be understood that when a layer is referred to as being ‘down/below/under/lower’ another layer, it can be directly under another layer, or one or more intervening layers may also be present. In addition, it will also be understood that when a layer is referred to as being ‘between’ two layers, it can be the only layer between the two layers, or one or more intervening layers may also be present. Thus, the meaning thereof must be determined based on the scope of the embodiment.

In the following description of the present invention, a detailed description of known functions and configurations incorporated herein will be omitted when it may make the subject matter of the present invention unclear.

FIGS. 1 to 6 are sectional views illustrating the procedure for manufacturing a semiconductor device according to an embodiment.

The semiconductor device according to the embodiment includes a transistor used for a CMOS image sensor.

Referring to FIG. 1, a gate oxide layer can be formed on a semiconductor substrate 100. In one embodiment, the gate oxide layer can have a thickness of about 90 Å to about 100 Å.

The gate oxide layer can be deposited on the semiconductor substrate 100 by using an FTP (furnace thermal process) under an atmosphere of oxygen and at a temperature of about 700° C. to about 900° C.

Then, a polysilicon layer can be formed on the gate oxide layer.

The polysilicon layer can be formed, for example, through LP-CVD (low pressure-chemical vapor deposition). In one embodiment, the polysilicon layer can have a thickness of about 1000 Å to about 5500 Å.

Next, the polysilicon layer and the gate oxide layer can be patterned to form a gate oxide layer pattern 110 on the semiconductor substrate 100 and a gate electrode 120 on the gate oxide layer pattern 110.

Then, impurities can be implanted at low concentration into the semiconductor substrate 100 at sides of the gate electrode 120 to form low concentration ion implantation regions 141.

Then, an insulating layer 130 for forming a spacer can be formed on the semiconductor substrate 100 including the gate electrode 120. The insulating layer can have an ONO (oxide-nitride-oxide) structure.

For example, the insulating layer 130 can include a first oxide layer 131, a nitride layer 132 and a second oxide layer 133, which are sequentially formed on the semiconductor substrate 100.

In an embodiment, the first and second oxide layers 131 and 133 can be formed through a CVD process at a temperature of about 600° C. to about 800° C. In one embodiment, the first oxide layer 131 can have a thickness of about 100 Å to about 300 Å and the second oxide layer 133 can have a thickness of about 500 Å to about 1500 Å.

At least one of the first and second oxide layers 131 and 133 can include a TEOS layer. The TEOS layer can be formed, for example, through CVD at a temperature of about 650° C. to about 700° C.

The nitride layer 132 can be formed through CVD at the temperature of about 650° C. to about 750° C. In one embodiment, the nitride layer can be formed to have a thickness of about 100 Å to about 300 Å.

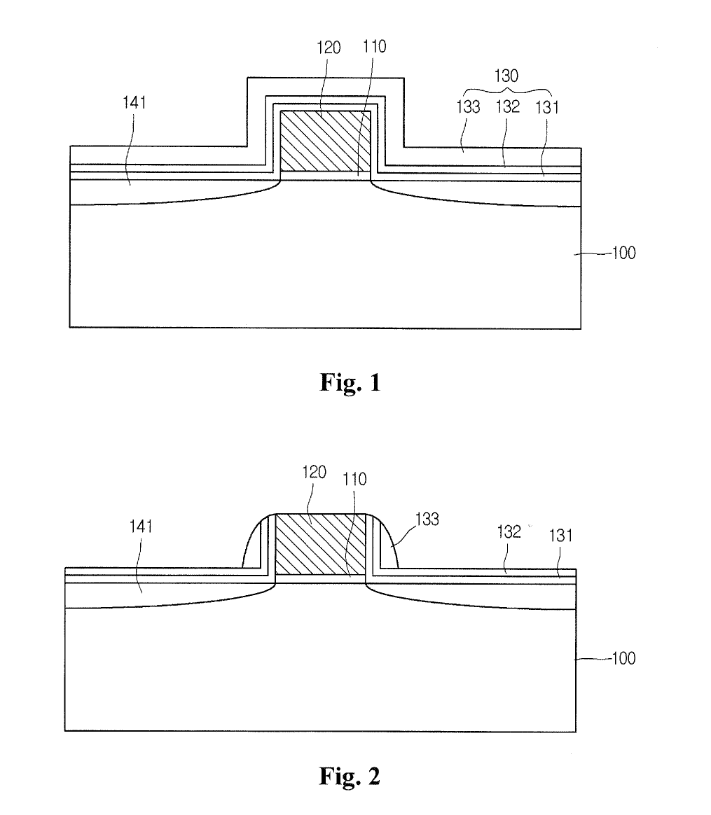

Referring to FIG. 2, the first oxide layer 131, the nitride layer 132 and the second oxide layer 133 can be subject to an etchback process through dry etching (anisotropic etching scheme), so that the first oxide layer 131 and the nitride layer 132 remain on the semiconductor substrate 100 at the sides of the gate electrode 120, and a part of the second oxide layer 133 remains on the sidewalls of the gate electrode 120 while partially covering the first oxide layer 131 and the nitride layer 132.

At this time, over-etching can be performed to reduce the thickness of the nitride layer 132. For example, the over-etching can be performed for about 2 seconds to about 5 seconds while setting the nitride layer 132 as an end point, so that the nitride layer 132 has a thickness of about 150 Å to about 200 Å according to etching selectivity.

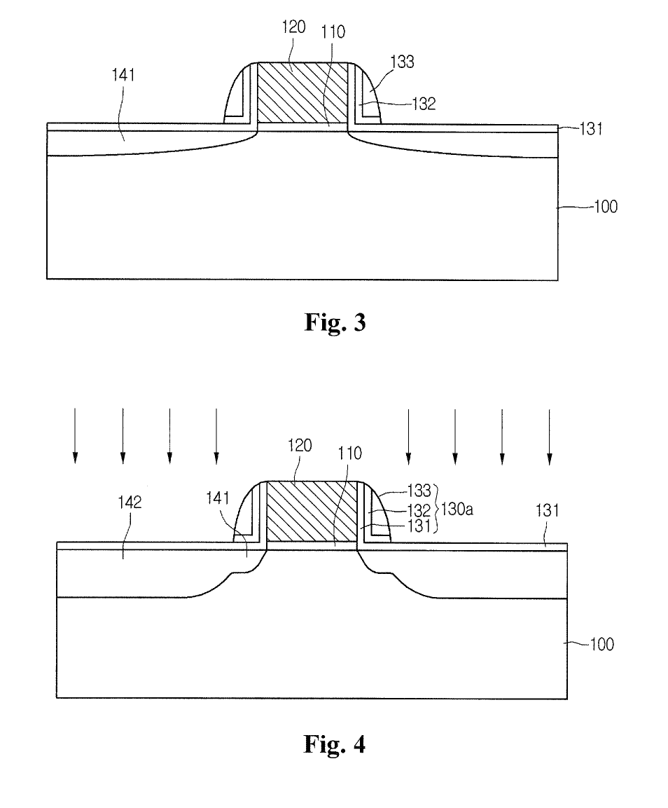

Then, as shown in FIG. 3, the nitride layer 132 on the semiconductor substrate 100 can be subject to a wet etch process with high etching selectivity.

In the wet etch process, the nitride layer can have a higher etching selectivity relative to the oxide layer in the ratio of (20 to 40):1.

As the wet etch process is performed, the nitride layer 132 is removed and the first oxide layer 131 remains on the semiconductor substrate 100.

During the wet etch process, the nitride layer 132 can be removed using H₃PO₄.

At this time, since the nitride layer 132 of the spacer formed on the sidewalls of the gate electrode 120 is covered by the second oxide layer 133, the nitride layer 132 can remain at the sidewalls according to the etching selectivity.

Since H₃PO₄ can etch the nitride layer 132 in the etching rate of 0.8 Å/sec to 0.9 Å/sec, the nitride layer 132 having the thickness of about 150 Å to about 200 Å can be completely removed by performing the wet etch process for about 250 seconds to about 300 seconds.

Then, a cleaning process can be performed for about 5 seconds to about 150 seconds by using an NC-2 cleaning solution (TMH: H₂O₂:H₂O=1:2 to 5:20 to 40) in order to remove particles generated after the wet etch process performed using H₃PO₄.

At this time, the first oxide layer 131 remaining on the semiconductor substrate 100 can be over-etched during the etching process of the nitride layer 132 to have a thickness of about 50 Å to about 150 Å. Further, the first oxide layer 131 at the sides of the gate electrode 120 can have a thickness different from that of the first oxide layer 131 on the sidewalls of the gate electrode 120.

Thus, a spacer 130a including the first oxide layer 131, the nitride layer 132 and the second oxide layer 133 can be formed on the sidewalls of the gate electrode 120 on the semiconductor substrate 100.

The first oxide layer 131 of the spacer 130a connects with the first oxide layer 131 on the semiconductor substrate 100 to form a single layer.

Then, referring to FIG. 4, impurities can be implanted at high concentration into the semiconductor substrate 100, so that impurity ions are implanted into the substrate at the sides of the gate electrode 120.

During the ion implantation process, the first oxide layer 131 serves as a barrier layer on the semiconductor substrate 100, so that plasma damage can be minimized. Thus, when voltage is applied to source and drain regions 142, current leakage due to surface defects can be inhibited from occurring, so that characteristics of the device can be improved.

The impurities can include N-type ions, such as boron (B), or P-type ions, such as phosphorus (P).

The impurities, which are implanted into the semiconductor substrate 100 at the sides of the gate electrode 120, form the source and drain regions 142.

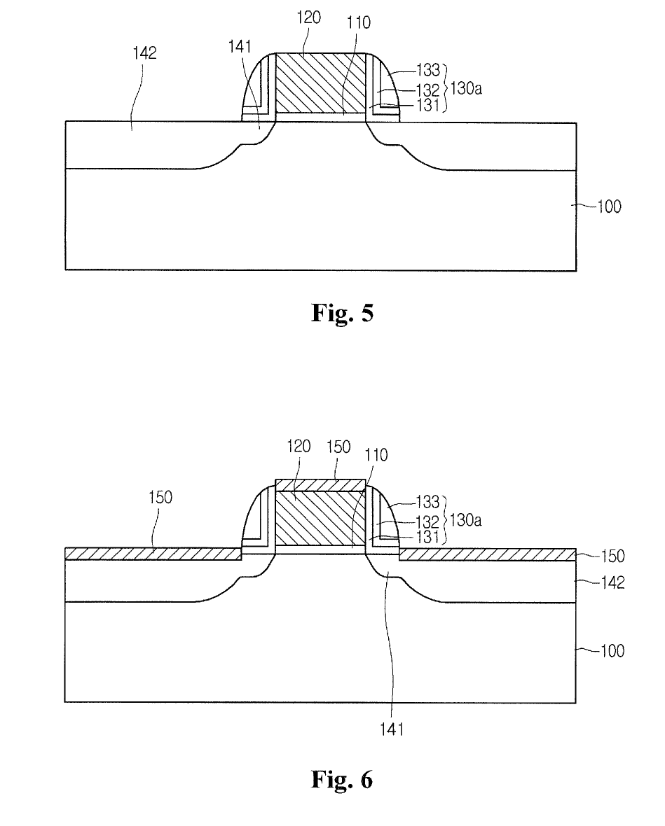

Then, referring to FIG. 5, the first oxide layer 131 remaining on the source and drain regions 142 can be removed through a wet etch process using DHF solution.

Then, as shown in FIG. 6, the upper surface of the gate electrode 120 and the surface of the source and drain regions 142 can be silicided to form a silicide pattern 150.

After forming the silicide pattern 150, a high concentration ion implantation process for forming the source and drain regions 142 can be performed one more time.

The semiconductor device formed in the sequence as described above can be applied to a high integrated semiconductor circuit using semiconductor manufacturing technology of 130 nm or less.

The transistor manufactured as described above can serve as a driving unit of the image sensor.

According to an embodiment, when forming the gate spacer in the semiconductor device, the remaining oxide layer can be formed on a silicide layer to inhibit plasma damage and current leakage from occurring, so that device characteristics of the CMOS image sensor can be improved.

According to an embodiment, current leakage of the driving transistor of the image sensor can be inhibited from occurring, so that characteristics of the image sensor can be improved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for manufacturing a semiconductor device, the method comprising:
forming a gate electrode on a semiconductor substrate;
sequentially forming a first oxide layer, a nitride layer and a second oxide layer on the semiconductor substrate on which the gate electrode is formed;
dry-etching the second oxide layer;
wet-etching the nitride layer; and
forming source and drain regions at sides of the gate electrode by implanting ions into the semiconductor substrate through the first oxide layer remaining on the semiconductor substrate after wet-etching the nitride layer.

2. The method according to claim 1, wherein during dry-etching the second oxide layer, the second oxide layer remains on sidewalls of the gate electrode.

3. The method according to claim 1, wherein, during wet-etching the nitride layer, the nitride layer located below the second oxide layer remaining after dry-etching the second oxide layer remains.

4. The method according to claim 1, wherein wet-etching the nitride layer comprises using H₃PO₄.

5. The method according to claim 1, further comprising, after wet-etching the nitride layer, performing a cleaning process relative to the semiconductor substrate by using an NC-2 solution (TMH: H₂O₂:H₂O=1:2 to 5:20 to 40).

6. The method according to claim 1, wherein dry-etching the second oxide layer comprises over-etching the nitride layer.

7. The method according to claim 6, wherein the nitride layer is over-etched to have a thickness of about 150 Å to about 200 Å.

8. The method according to claim 1, wherein wet-etching the nitride layer comprises over-etching the first oxide layer.

9. The method according to claim 8, wherein the first oxide layer is over-etched to have a thickness of about 50 Å to about 150 Å.

10. The method according to claim 1, further comprising, after forming the source and drain regions:
removing the first oxide layer remaining on the semiconductor substrate; and
forming a silicide pattern on an upper surface of the source and drain regions and an upper surface of the gate electrode.

11. The method according to claim 1, wherein during the wet-etching of the nitride layer, the nitride layer has a higher etching selectivity relative to the oxide layer in a ratio of (20 to 40):1.

12. A method for manufacturing a semiconductor device, the method comprising:
forming a gate electrode on a semiconductor substrate;
forming an insulating layer on the semiconductor substrate on which the gate electrode is formed;
etching the insulating layer such that a part of the insulating layer remains on both the semiconductor substrate at sides of the gate electrode and on sidewalls of the gate electrode;
forming source and drain regions at both sides of the gate electrode by implanting ions into the semiconductor substrate through the part of the insulating layer remaining on the semiconductor substrate at sides of the gate electrode; and
removing the part of the insulating layer remaining on the semiconductor substrate at sides of the gate electrode.

13. The method according to claim 12, wherein forming the insulating layer comprises:
forming a first oxide layer on the semiconductor substrate such that the first oxide layer covers the gate electrode;
forming a nitride layer on the first oxide layer; and
forming a second oxide layer on the nitride layer.

14. The method according to claim 12, wherein the part of the insulating layer remaining on the semiconductor substrate at the sides of the gate electrode comprises a first oxide layer.

15. The method according to claim 12, wherein the part of the insulating layer remaining on the sidewalls of the gate electrode comprises a first oxide layer, a nitride layer and a second oxide layer.

16. The method according to claim 12, further comprising, after removing the part of the insulating layer remaining on the semiconductor substrate at sides of the gate electrode:
siliciding an upper surface of the gate electrode and a surface of the source and drain regions.

17. The method according to claim 12, further comprising, after removing the part of the insulating layer remaining on the semiconductor substrate at sides of the gate electrode:
performing a high concentration ion implantation process relative to the source and drain regions.

18. The method according to claim 12, further comprising, after forming the gate electrode on the semiconductor substrate:
implanting impurities at low concentration into the semiconductor substrate at the sides of the gate electrode.
